(19) United States
(12) Patent Application Publication
(10) Pub. No.: US 2023/0366076 A1
(43) Pub. Date: Nov. 16, 2023

(54) SUPPORT STRIP AND NET-TENSIONING METHOD

(71) Applicant: KunShan Go-Visionox Opto-Electronics Co., Ltd, Kunshan (CN)

(72) Inventors: Dingfan ZHAO, Kunshan (CN); Mingxing LIU, Kunshan (CN); Jingjing ZHAO, Kunshan (CN); Jia FU, Kunshan (CN)

(73) Assignee: KunShan Go-Visionox Opto-Electronics Co., Ltd, Kunshan (CN)

(21) Appl. No.: 18/358,445

(22) Filed: Jul. 25, 2023

Related U.S. Application Data
(63) Continuation of application No. PCT/CN2022/088129, filed on Apr. 21, 2022.

(30) Foreign Application Priority Data
Aug. 6, 2021 (CN) 202110903244.0

(51) Int. Cl. C23C 14/04; C23C 14/24

(52) U.S. Cl. CPC C23C 14/042; C23C 14/24

(57) ABSTRACT

A support strip and a method of new tensioning. The support strip includes a support segment and a predetermined cutting segment. Each of two ends of the support segment is connected with the predetermined cutting segment in a length direction of the support strip. The support segment includes a support body and a covering portion. The support body extends in a length direction. The covering portion is located at a first side of the support body. A second side of the support body is opposite to the first side in a width direction perpendicular to the length direction. The predetermined cutting segment comprises an offset-compensating portion. A first side edge of the offset-compensating portion extends in the length direction. A second side edge of the offset-compensating portion is inclined from the second side to the first side.

### CROSS REFERENCE TO RELATED APPLICATION

The present application is a continuation of International Application No. PCT/CN2022/088129, filed on Apr. 21, 2022, which claims priority to Chinese Patent Application No. 202110903244.0, filed on Aug. 6, 2021, titled “SUPPORT STRIP AND NET-TENSIONING METHOD”, both of which are hereby incorporated by reference in their entireties.

### FIELD

The present application relates to the technical field of evaporation device, and in particular to a support strip and a net-tensioning method.

### BACKGROUND

Evaporation is a common process method in a manufacturing process of an organic light-emitting diode (OLED) display panel. During an evaporation process, the evaporation material is generally evaporated onto a to-be-evaporated substrate through a mask. When manufacturing a display panel with a functional integration region, a special support strip can be used to shield a part of a to-be-evaporated region on the to-be-evaporated substrate and at the same time support a mask bar. The above-mentioned special support strip is prone to deviation relative to a stretch direction during the stretching process, so that it may cause the problems such as abnormal evaporation and low evaporation precision in the functional integration region, which can affect the overall display effect of the display panel.

### SUMMARY

The object of the present application is to provide a support strip and a net-tensioning method, at least to solve the problem that the support strip used for evaporation is prone to deviation relative to a stretch direction during a net-tensioning process.

A first aspect of an embodiment in the present application provides a support strip. The support strip includes a support segment and a predetermined cutting segment. Each of two ends of the support segment is connected with the predetermined cutting segment in a length direction of the support strip. The support segment includes a support body and a covering portion. The support body extends in a length direction. The covering portion is located at a first side of the support body. A second side of the support body is opposite to the first side in a width direction perpendicular to the length direction. The predetermined cutting segment includes an offset-compensating portion. A first side edge of the offset-compensating portion extends in the length direction. A second side edge of the offset-compensating portion is inclined from the second side to the first side to gradually decrease a width of at least part of the offset-compensating portion from the support body to a free end.

The first aspect of the embodiment of the present application provides the support strip for a mask. The offset-compensating portion is arranged on the predetermined cutting segment of the support strip, so that a non-stretching-direction offset value can be reduced, and a net-tensioning accuracy of the support strip can be further improved. Therefore, it can ensure the alignment accuracy between the covering portion and a predetermined functional integration region on the to-be-evaporated substrate, improve the evaporation accuracy, avoid deposition of evaporation materials in a functional integration region, and improve the overall display effect of the display panel.

A second aspect of the embodiment of the present application provides a net-tensioning method for performing a net-tensioning process to the support strip in the first aspect, including:
stretching in the length direction the two offset-compensating portions opposite to each other in the length direction to obtain the tensioned support strip;
welding the tensioned support strip on a mask frame; and
removing the predetermined cutting segment.

The second aspect of the embodiment of the present application provides the net-tensioning method, so that it can reduce the non-stretching-direction offset value, improve the net-tensioning accuracy of the support strip on the mask after being tensioned, further improve a shielding accuracy of the predetermined function integration region by the covering portion, and improve the display effect of the display panel.

### BRIEF DESCRIPTION OF THE DRAWINGS

FIG. 1 shows a schematic view of a general support strip including a covering portion in a net-tensioning state;

FIG. 2 shows a schematic structural view of a support strip in an embodiment of a first aspect of the present application;

FIG. 3 shows a schematic structural view of a support strip in another embodiment of a first aspect of the present application;

FIG. 4 shows a schematic structural view of a support strip in another embodiment of a first aspect of the present application;

FIG. 5 shows a schematic structural view of a support strip in another embodiment of a first aspect of the present application;

FIG. 6 shows a schematic structural view of a support strip in another embodiment of a first aspect of the present application;

FIG. 7 shows a schematic structural view of a support strip in a net-tensioning state in an embodiment of a first aspect of the present application;

FIG. 8 shows a schematic structural view of a support strip in another embodiment of a first aspect of the present application;

FIG. 9 shows a schematic structural view of a support strip in another embodiment of a first aspect of the present application;

FIG. 10 shows a schematic structural view of a support strip in another embodiment of a first aspect of the present application;

FIG. 10a shows an enlarged schematic view of part A in FIG. 10;

FIG. 10b shows an enlarged schematic view of part B in FIG. 10;

FIG. 11 shows a schematic structural view of a support strip in a net-tensioning state in an embodiment of a first aspect of the present application; and

FIG. 12 shows a flow chart of a method of net-tensioning in a second aspect of the present application.

### DETAILED DESCRIPTION

Features and exemplary embodiments in various aspects of the present application will be described in detail below. In order to make the objects, technical solutions and advantages of the present application clearer, the present application will be further described in detail below in conjunction with the drawings and the specific embodiments. It should be understood that the specific embodiments described here are only configured to explain the present application, not to limit the present application. It is apparent to one skilled in the art that the present application can be practiced without some of these specific details. The description of the embodiments below is only to provide a better understanding of the present application by showing examples of the present application.

It should be noted that, in the present application, the relational terms such as first, second and the like are merely used to distinguish one entity or operation from another and do not necessarily require or imply any such actual relationship or relationship between these entities or operations. In addition, the term “include”, “comprise” or any other variation thereof is intended to cover a non-exclusive inclusion, such that a process, method, article or device including a set of elements includes not only those elements but also other elements which are not expressly listed, or but also the elements inherent to such a process, method, article or device. Without further limitations, an element defined by the statement “including . . . ” does not exclude the presence of additional same elements in the process, method, article or device including said element.

The inventor has found through a long-term in-depth research that evaporation is a commonly used process in a process of manufacturing an OLED display panel. During the evaporation process, an evaporation material is generally evaporated onto a to-be-evaporated substrate through a mask. When manufacturing a display panel with a functional integration region, a special support strip can be used to shield a part of a to-be-evaporated region on the to-be-evaporated substrate and at the same time support a mask bar. Generally, a side of the special support strip can be provided with a covering portion. The covering portion can be used for shielding the evaporation material, so that the evaporation material will not be deposited in a predetermined functional integration region on the to-be-evaporated substrate, and the functional integration region of the display panel will not perform luminescent display after manufacturing. The functional integration region generally integrates a camera, a face recognition sensor and other functional modules. The functional integration region cannot deposit the evaporation material.

When manufacturing the mask, it is necessary to stretch the support strip provided with the covering portion in a length direction of the support strip, so that the support strip can be welded to a mask frame after being stretched. Generally, during a net-tensioning process, since the cover portion is generally concentrated at a side of the support strip, the side and the other side (the other side is opposite to the side at which the covering portion is provided in a width direction of the support strip) of the cover portion of the support strip are both inwardly contracted and deformed under a stretching force of net-tensioning. During shrinking and deforming, since the covering portion at the side where the covering portion is provided shrinks under the net-tensioning stretching force, a superimposed shrinkage effect occurs on the side where the covering portion is provided on the support strip.

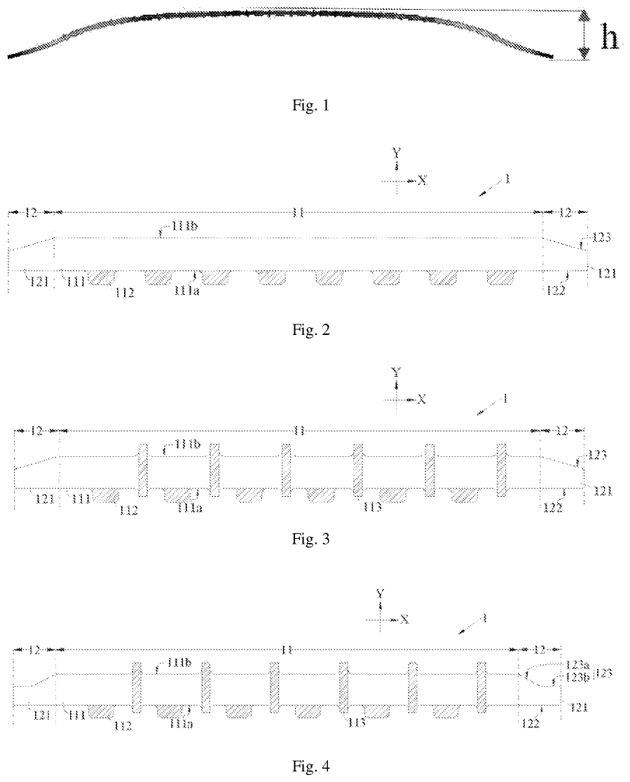

Therefore, as shown in FIG. 1, during the net-tensioning process of the support strip, a pressing effect of one side of the covering portion to the other side of the covering portion can be arranged to be greater than a pressing effect of the other side of the covering portion to the one side of the covering portion, finally the overall support strip may produce a convex deformation towards the other side and form an offset place in a non-stretching direction. The inventor further finds that, generally, when the support strip occurs the offset place in the non-stretching direction, a non-stretching-direction offset value of a middle part of the support strip can be greater than non-stretching-direction offset values of two sides of the support strip. In the embodiment of the present application, the non-stretching-direction offset value h can be defined a distance from any part of the support strip to a straight line where a stretching direction is located in a width direction perpendicular to the stretching direction (the length direction of the support strip).

In view of the discovery and analysis of the above problems, the present application is proposed.

As shown in FIG. 2, a first aspect of the embodiment in the present application provides the support strip 1 for the mask. The support strip 1 includes a support segment 11 and a predetermined cutting segment 12. Each of two ends of the support segment 11 can be connected with the predetermined cutting segment 12 in a length direction X of the support strip 1.

The support segment 11 may include a support body 111 and at least one covering portion 112. The support body 111 may extend in the length direction X of the support strip 1. The at least one covering portion 112 can be located at a first side 111a of the support body 111, and a second side 111b of the support body 111 is opposite to the first side 111a of the support body 111 in a width direction Y perpendicular to the length direction X.

The predetermined cutting segment 12 may include an offset-compensating portion 121. A first side edge 122 of the offset-compensating portion 121 extends in the length direction X. A second side edge 123 of the offset-compensating portion 121 may be inclined from the second side 111b of the support body 111 to the first side 111a of the support body 111, so as to gradually decrease a width of at least part of the offset-compensating portion 121 from the support body 111 to a free end. In the length direction X of the support strip 1, the free end of the predetermined cutting segment 12 may be an end of the predetermined cutting segment 12 away from the support segment 11.

In some embodiments, a plurality of covering portions 112 can be arranged, and the plurality of covering portions 112 can be arranged on the first side 111a of the support body 111 and distributed to be spaced from one another in the length direction X of the support strip 1.

The first aspect of the embodiment of the present application provides the support strip 1 for the mask. The offset-compensating portion 121 can be provided on the predetermined cutting segment 12 of the support strip 1. During the net-tensioning process of the support strip 1, a net-tensioning mechanism can clamp the offset-compensating portion 121 of the support strip 1, and perform the net-tensioning process to the support strip 1 in the length direction X of the support strip 1. Since the width of at least part of the offset-compensating portion 121 gradually decreases from the support body 111 to the free end and gradually decreases toward the first side 111a of the support body 111, a clamping centerline of a clamping mechanism offsets toward the first side 111a. The offset of the clamping centerline makes the net-tensioning stretching force also offset towards the first side 111a, so that it may reduce the pressing effect of the covering portion 112 on the first side 111a of the support body 111 to the second side 111b towards the support body 111 during the net-tensioning process, and the non-stretching-direction offset value of the support strip 1 towards the second side 111b of the support body 111 can be reduced. The non-stretching-direction offset value can be reduced, and a net-tensioning accuracy of the support strip 1 can be further improved. Therefore, it can ensure the alignment accuracy between the covering portion 112 and a predetermined functional integration region on the to-be-evaporated substrate, improve the evaporation accuracy, avoid deposition of evaporation materials in a functional integration region, and improve the overall display effect of the display panel.

In some embodiments, the support body 111 of the support segment 11 and the predetermined cutting segment 12 in the support strip 1 may be full-thickness structures, it means that the thinning treatment such as etching or the like is no longer performed, so that it is beneficial for the support body 111 to realize the support function and realize the clamping stability of the predetermined cutting segment 12 during the net-tensioning process. The covering portion 112 can be processed in a half-etching process, so that it can reduce the overall weight load of the first side 111a of the support body 111 while ensure the covering effect of the covering portion 112 on the predetermined functional integration region, and further avoid the offset in the non-stretching direction.

As shown in FIG. 3, in some embodiments, a shielding strip engaging portion 113 can be arranged on the support body 111 of the support segment 11. The shielding strip engaging portion 113 can be arranged between two adjacent covering portions 112, and the shielding strip engaging portion 113 can be a half-etching structure, so that it is beneficial for the cooperation between the support strips 1 arranged to overlap with one another during the process of forming the mask and the shielding strip engaging portion 113. In the case that the number of covering portions 112 is greater than two, a plurality of shielding strip engaging portion 113 can be arranged. The plurality of shielding strip engaging portion 113 can be arranged to be spaced apart from one another. In the width direction Y, the shielding strip engaging portion 113 extends in the width direction Y, and a width of the shielding strip engaging portion 113 can be greater than a width of the support body 111. A rounded chamfer can be formed at a connecting place between the shielding strip matching portion 113 and the support body 111.

In some optional embodiments, the second side edge 123 may be a straight-line side edge. The overall segment of the second side edge 123 may be the straight-line side on a same horizontal line. The second side edge 123 has no bent point. Referring to FIG. 2 and FIG. 3, in some examples, the second side edge 123 may be inclined from the second side 111b of the support body 111 to the first side 111a, and the second side edge 123 may extend from the second side 111b of the support body 111 to the free end of the offset-compensating portion 121.

As shown in FIG. 4, in some examples, the second side edge 123 is a straight-line side edge and the second side edge 123 is a multi-segment-bent straight-line side edge composed of at least two straight-line segments. In these embodiments, the second side edge 123 includes a first straight-line segment 123a and a second straight-line segment 123b. The first straight-line segment 123a may incline and extend from the second side 111b of the support body 111 to the first side 111a, and the first straight-line segment 123a may extend to a middle part of the offset-compensating portion 121 to adjoin with the second straight-line segment 123b. The second straight-line segment 123b may extend to the free end of the offset-compensating portion 121, and the second straight-line segment 123b may be relatively parallel to the first side edge 122.

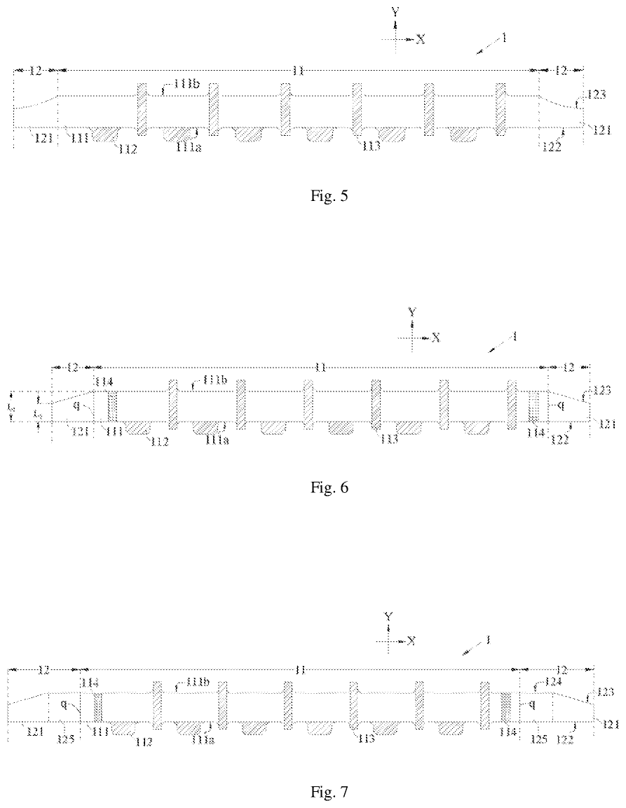

As shown in FIG. 5, in some embodiments, the second side edge 123 may be an arc-line side edge.

As shown in FIG. 6, in some optional embodiments, a maximum width L1 of the offset-compensating portion 121 and a minimum width L2 of the offset-compensating portion 121 satisfy Relation 1 as follows:

$$5 \% ⩽ \frac{L 1 - L 2}{L 1} ⩽ 6 \% . \qquad Relation 1$$

In some examples, the maximum width of the offset-compensating portion 121 is the width of the support body 111. During the experiment, generally, the maximum non-stretching-direction offset value of the support strip 1 with the covering portion 112 may be approximately 330 μm-340 μm. The inventor finds that when the maximum width L1 of the offset-compensating portion 121 and the minimum width L2 of the offset-compensating portion 121 satisfy the above Relation 1, the non-stretching-direction offset value of the support strip 1 decreases significantly in the net-tensioning process of the support strip 1, and the maximum non-stretching-direction offset value decreases to 60 μm-100 μm.

Further, in some optional embodiments, the maximum width L1 of the offset-compensating portion and the minimum width L2 of the offset-compensating portion satisfy Relation 1 as follows:

$$5.45 \% ⩽ \frac{L 1 - L 2}{L 1} ⩽ 5.46 \% . \qquad Relation 2$$

In these embodiments, when the maximum width L1 of the offset-compensating portion 121 and the minimum width L2 of the offset-compensating portion 121 satisfy the above Relation 2, the non-stretching-direction offset value of the support strip 1 decreases significantly in the net-tensioning process of the support strip 1, and the maximum non-stretching-direction offset value decreases to 60 μm-80 μm.

In some optional embodiments, the support segment 11 can be arranged adjacent to the predetermined cutting segment 12 in the length direction X, a predetermined cutting line q can be formed between the support segment 11 and the predetermined cutting segment 12, and the support segment 11 and the predetermined cutting segment 12 may be divided by the predetermined cutting line q. In some examples, the support segment 11 and the predetermined cutting segment 12 may be integrally formed of a same material. During a process of manufacturing the precision mask, after tensioning the support strip 1, the support segment 11 may be welded on the mask frame, and then the predetermined cutting segment 12 can be cut and removed along the predetermined cutting line q.

In some embodiments, the plurality of covering portions 112 are arranged at the first side 111a of the support body 111 and distributed to be spaced apart from one another in the length direction X. The support body 111 may further include a welding groove 114. The welding groove 114 can be located between the predetermined cutting line q and the covering portion 112 closest to the predetermined cutting segment 12. During a welding process, the welding groove 114 can be aligned with the mask frame. The fixed connection between the support segment 11 and the mask frame can be realized by welding the welding groove 114 to the mask frame.

In the embodiments of the present application, the support strip 1 may include the predetermined cutting line q and the welding groove 114. For brief illustration, the predetermined cutting line q and the welding groove 114 are not fully shown in the drawings corresponding to the following embodiments.

As shown in FIG. 7, in some optional embodiments, the predetermined cutting segment 12 may further include a buffer portion 125. The buffer portion 125 may be located between the support segment 11 and the offset-compensating portion 121. The buffer portion 125 may further include a transition side edge 124. The transition side edge 124 may extend along a straight line from the second side 111b of the support body 111 to the second side edge 123. An extending direction of the first side edge 122 and an extending direction of the transition side edge 124 are parallel to each other.

In these embodiments, the buffer portion 125 can protect the support segment 11 from being disturbed during the net-tensioning process and the subsequent processes of welding and cutting to remove the predetermined cutting segment 12, so as to improve the quality of the mask being manufactured and improve the evaporation precision.

In some embodiments, in the length direction X, a value range of a length of the transition side edge 124 may be 20 mm-25 mm.

In some embodiments, in the length direction X, the value range of the length of the transition side edge 124 may be 24 mm-25 mm.

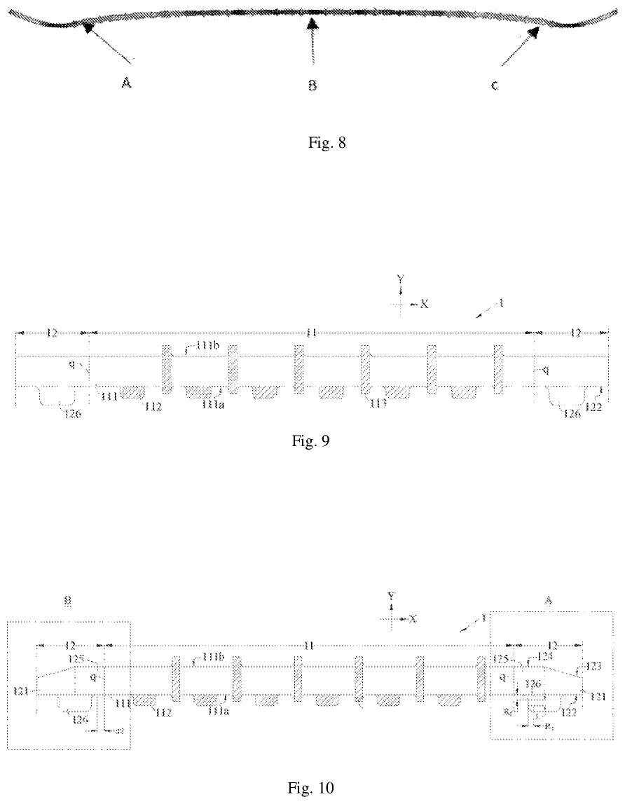

FIG. 8 shows a state view of the support strip 1 with the offset-compensating portion 121 during the net-tensioning process in an example. As shown in FIG. 8, the inventor further finds that the maximum non-stretching-direction offset value of the support strip 1 with the offset-compensating portion 121 can be significantly reduced during the net-tensioning process. However, the support segment 11 of the support strip 1 may form three segments A, B and C in FIG. 8. The segment A and the segment C are close to the predetermined cutting segment 12. The non-stretching-direction offset values of segment A and segment C are between 60 μm and 80 μm. The non-stretching-direction offset has a large degree and tends to offset toward the first side 111a of the support body 111. The segment B may be located in a middle part of the support segment 11, and the non-stretching-direction offset of segment B can be less than or equal to 5 μm. According to the above experimental analysis, arranging the offset-compensating portion 121 has a good effect on reducing the non-stretching-direction offset value of the support strip 1 as a whole, especially for the middle part of the support segment 11. On the basis of arranging the offset-compensation portion 121, it is necessary to further optimize the structure of the support strip 1, so as to further reduce non-stretching-direction offset-compensating values of the two segments (segment A and segment B) of the support segment 11 close to the predetermined cutting segment 12.

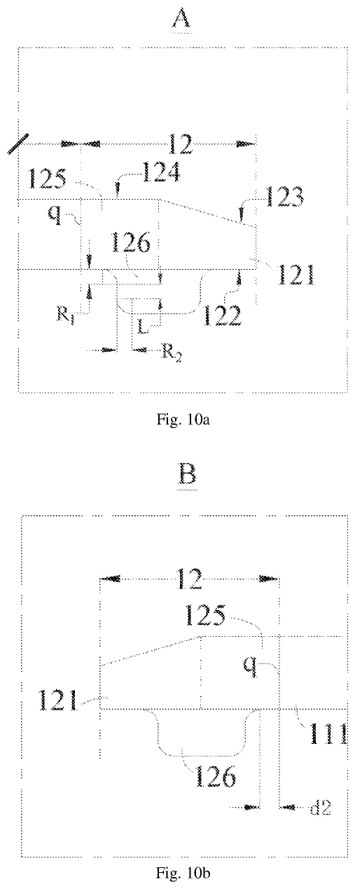

As shown in FIG. 9, in some embodiments, in order to further reduce the non-stretching-direction offset-compensating value of the portion of the support segment 11 close to the predetermined cutting segment 12, generally a new counterweight design can be added to the support strip 1. As shown in FIG. 10, FIG. 10a and FIG. 10b, in some embodiments, In order to further reduce the non-stretching-direction offset-compensating value of the part of the support segment 11 close to the predetermined cutting segment 12, the support strip 1 can be provided with a counterweight portion 126 on the basis of having the offset-compensating portion 121.

In some embodiments, the counterweight portion 126 can be added to the predetermined cutting segment 12 of the support strip 1. The counterweight portion 126 can be arranged at a same side as the covering portion. The counterweight portion 126 protrudes from and is arranged at the first side edge 122. In some embodiments, a shape of the counterweight portion 126 may be same as a shape of the covering portion 112, and a size of the counterweight portion 126 may be different from a size of the covering portion 112. In some embodiments, the size of the counterweight portion 126 is larger than the size of the covering portion 112. The counterweight portion 126 may be a quasi-rectangular sheet-like structure, and the counterweight portion 126 may be a sheet-like structure extending from the first side 111a of the support body 111 towards a direction away from the second side 111b of the support body 111. A rounded chamfer can be formed at a connecting place between the counterweight portion 126 and the first side edge 122, and a corner of the counterweight portion 126 may be a rounded corner. In some embodiments, the counterweight portion 126 may be a full-thickness structure, and does not use the half-etching process. The full-thickness structure of the counterweight portion 126 can increase the counterweight of the first side 111a of the predetermined cutting segment 12 (the same side as the first side 111a of the support body 111), and further reduce the weight of the part of the support segment 11 close to the predetermined cutting segment 12.

In some embodiments, as shown in FIG. 10, FIG. 10a and FIG. 10b, the predetermined cutting segment 12 may further include the buffer portion 125. The buffer portion 125 may include a transition side edge 124, the transition side edge 124 may extend along a straight line from the second side 111b of the support body 111 to the second side edge 123, and an extending direction of the first side edge 122 and an extending direction of the transition side edge 124 may be parallel to each other. In the length direction X, the counterweight portion 126 can be arranged to correspond to a part of the transition side edge 124 and a part of the second side edge 123. In the length direction X, a part of the predetermined cutting segment 12 corresponding to the transition side edge 124 can be located between the support segment 11 and the offset-compensating portion 121. The part corresponding the transition side edge 124 can protect the support segment 11 from not being disturbed during the net-tensioning process and the subsequent processes of welding and cutting to remove the predetermined cutting segment 12, so as to improve the quality of the mask being manufactured and improve the evaporation precision.

In some embodiments, the size of the counterweight portion 126 is larger than the size of the covering portion 112. The counterweight portion 126 may be a quasi-rectangular sheet-like structure, and the counterweight portion 126 may be a sheet-like structure extending from the first side 111a of the support body 111 towards a direction away from the second side 111b of the support body 111. The rounded chamfer can be formed at the connecting place between the counterweight portion 126 and the first side edge 122. A value range of a radius R1 of the rounded chamfer may be 2.0 mm-2.5 mm. Further, the value range of a radius R1 of the rounded chamfer may be 2.1 mm-2.2 mm. The corner of the counterweight portion 126 may be the rounded corner. A value range of a radius R2 of the corner may be 1.0 mm-1.5 mm. Further, the value range of the radius R2 of the corner may be 1.1 mm-1.2 mm. In the width direction Y, the counterweight portion 126 may include a straight side parallel to the width direction Y. The straight edge may be located between the rounded chamfer and the corner. A value range of a length L of the straight side may be 1.0 mm-1.2 mm. Further, the value range of the length L of the straight side may be 1.10 mm-1.15 mm.

In some optional embodiments, in the length direction X, a value range of a shortest distance d2 between the predetermined cutting line q and the counterweight portion 126 may be 4 mm-5 mm. In these embodiments, the shortest distance between the predetermined cutting line q and the counterweight portion 126 may be a shortest distance between support segment 11 and the counterweight portion 126.

In some embodiments, in the length direction X, a ratio of the shortest distance d2 between the predetermined cutting line q and the counterweight portion 126 to the length of the transition side edge 124 may be 1:6-1:5. In some embodiments, the length dl of the transition side edge 124 may be a shortest distance from the offset-compensating portion 121 to the support segment 11. A ratio of the shortest distance d2 between the predetermined cutting line q and the counterweight portion 126 to the shortest distance from the offset-compensating portion 121 to the support segment 11 may be 1:6-1:5. It can be ensured that the non-stretching offset-compensating value of the support segment 11 close to the predetermined cutting segment 12 can be reduced to an allowable range, while ensuring that the non-stretching-direction offset-compensating value in a middle part of the support segment 11 can be reduced to the allowable range. The difference between the non-stretching-direction offset-compensating value in the middle part of the support segment 11 and the non-stretching-direction offset-compensating value of the support segment 11 close to the predetermined cutting segment 12 can be reduced, so that it can improve the net-tensioning accuracy, thereby ensuring the evaporation accuracy of the functional integration region and improving the display effect of the display panel.

In some embodiments, the support strip 1 can be provided with the counterweight portion 126 on the basis of having the offset-compensating portion 121. The second side edge 123 of the offset-compensating portion 121 is the straight-line side edge. The maximum width L1 of the offset-compensating portion 121 and the minimum width L2 of the offset-compensating portion 121 satisfy the above Relation 2. The support segment 11 can be arranged adjacent to the predetermined cutting segment 12 in the length direction X, and the predetermined cutting line q can be formed between the support segment 11 and the predetermined cutting segment 12. The predetermined cutting segment 12 may further include the buffer portion 125. The buffer portion 125 may include the transition side edge 124, the transition side edge 124 may extend along the straight line from the second side 111b of the support body 111 to the second side edge 123, and the extending direction of the first side edge 122 and the extending direction of the transition side edge 124 may be parallel to each other. In the length direction X, the counterweight portion 126 can be arranged to correspond to the part of the transition side edge 124 and the part of the second side edge 123. The support body 111 may further include the welding groove 114. The welding groove 114 can be located between the predetermined cutting line q and the covering portion 112 closest to the predetermined cutting segment 12, and the welding groove 114 further can be located between the predetermined cutting line q and the shielding strip engaging portion 113 closest to the predetermined cutting segment 12. The counterweight portion 126 may be the quasi-rectangular sheet-like structure, and the counterweight portion 126 may be the sheet-like structure extending from the first side 111a of the support body 111 towards a direction away from the second side 111b of the support body 111. The rounded chamfer can be formed at the connecting place between the counterweight portion 126 and the first side edge 122. The value range of a radius R1 of the rounded chamfer may be 2.1 mm-2.2 mm. The corner of the counterweight portion 126 may be the rounded corner. The value range of a radius R2 of the corner may be 1.1 mm-1.2 mm. In the width direction Y, the counterweight portion 126 may include the straight side parallel to the width direction Y. The value range of a length L of the straight side may be 1.10 mm-1.15 mm. In the length direction X, the value range of the shortest distance d2 between the predetermined cutting line q and the counterweight portion 126 may be 4 mm-5 mm. In the length direction X, the ratio of the shortest distance d2 between the predetermined cutting line q and the counterweight portion 126 to the length d1 of the transition side edge 124 may be 1:6-1:5.

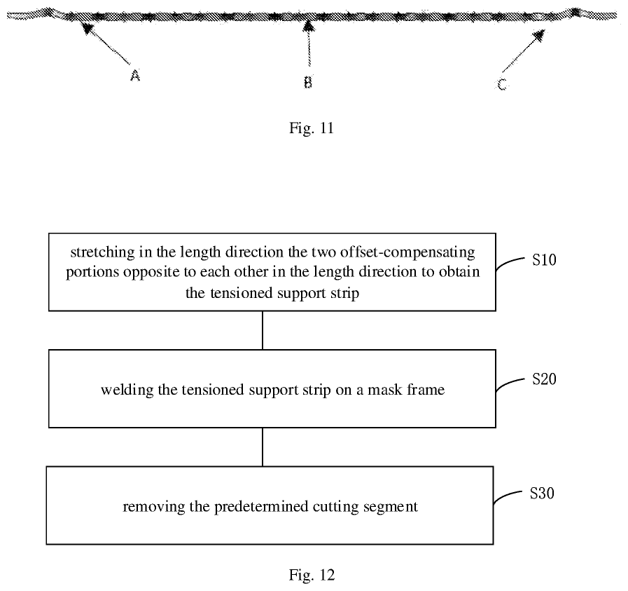

As shown in FIG. 11, a net-tensioning experiment can be carried out on the above-mentioned embodiments, so that it can be obtained that the non-stretching-direction offset value of the middle part (segment B) of the support segment 11 may be less than or equal to 4 μm, and the non-stretching-direction offset values of the two parts (segment A and segment B) of the support segment 11 close to the predetermined cutting segment 12 may be less than or equal to 4 μm. According to the experimental results, it can be known that arranging the offset-compensating portion 121 and the counterweight portion 126 on the support strip 1 at the same time can greatly reduce the non-stretching-direction offset degree of the overall support segment 11 and ensure the net-tensioning accuracy of the support strip 1, improve the shielding accuracy of the predetermined functional integration region by the covering portion 112, further improve the evaporation accuracy near the predetermined functional integration region of the to-be-evaporated substrate and optimize the display effect of the display panel.

As shown in FIG. 12, a second aspect of the embodiment of the present application provides a net-tensioning method for performing the net-tensioning process to the support strip in the first aspect of the embodiment of the present application, including:
S10, stretching the two offset-compensating portions opposite to each other in the length direction in the length direction to obtain the tensioned support strip;
S20, welding the tensioned support strip on a mask frame; and
S30, removing the predetermined cutting segment.

In some optional embodiments, when the net-tensioning mechanism is used to tension the support strip, a clamping component can clamp at least part of the offset-compensating portion, so that the clamping centerline offsets toward the first side of the support segment. The net-tensioning mechanism stretches the two offset-compensating portions opposite to each other in the length direction of the support strip in the length direction of the support strip, so that the support strip can be stretched in the length direction of the support strip to form the tensioned support strip.

The second aspect of the embodiment of the present application provides the net-tensioning method, so that it can reduce the non-stretching-direction offset value, improve the net-tensioning accuracy of the support strip on the mask after being tensioned, further improve the shielding accuracy of the predetermined function integration region by the covering portion, and improve the display effect of the display panel.

In accordance with the embodiments of the present application described above, these embodiments do not describe all details in detail, nor do they limit the present invention to only the specific embodiments described above. Obviously, many modifications and variations are possible in light of the above description. The description selects and specifically describes these embodiments in order to better explain the principles and practical applications of the present application, so that those skilled in the art can make good use of the present application and the modifications based on the present application. The present application is to be limited only by the claims, along with their full scope and equivalents.

What is claimed is:

1. A support strip, comprising:
a support segment, the support segment comprising a support body and at least one covering portion, the support body extending in a length direction, the at least one covering portion being located at a first side of the support body, a second side of the support body being opposite to the first side in a width direction perpendicular to the length direction;
a predetermined cutting segment, the predetermined cutting segment comprising an offset-compensating portion, a first side edge of the offset-compensating portion extending in the length direction, a second side edge of the offset-compensating portion being inclined from the second side to the first side to gradually decrease a width of at least part of the offset-compensating portion from the support body to a free end,
wherein each of two ends of the support segment is connected with one corresponding predetermined cutting segment in the length direction of the support strip.

2. The support strip according to claim 1, wherein the second side edge of the offset-compensating portion is a straight-line side edge; or the second side edge of the offset-compensating portion is an arc-line side edge.

3. The support strip according to claim 1, wherein the second side edge of the offset-compensating portion comprises at least two straight-line segments.

4. The support strip according to claim 1, wherein a maximum width L1 of the offset-compensating portion and a minimum width L2 of the offset-compensating portion satisfy Relation 1 as follows:
$$5 \% ⩽ \frac{L 1 - L 2}{L 1} ⩽ 6 \% . \qquad Relation 1$$

5. The support strip according to claim 4, wherein the maximum width L1 of the offset-compensating portion and the minimum width L2 of the offset-compensating portion satisfy Relation 2 as follows:
$$5.45 \% ⩽ \frac{L 1 - L 2}{L 1} ⩽ 5.46 \% . \qquad Relation 2$$

6. The support strip according to claim 1, wherein the support segment is arranged adjacent to the predetermined cutting segment in the length direction, a predetermined cutting line is arranged between the support segment and the predetermined cutting segment, and the support segment and the predetermined cutting segment are divided by the predetermined cutting line.

7. The support strip according to claim 6, further comprising a plurality of covering portions, the plurality of covering portions are arranged at the first side of the support body and distributed to be spaced apart from one another in the length direction, the support body further comprises a welding groove, and the welding groove is located between the predetermined cutting line and the covering portion close to the predetermined cutting segment.

8. The support strip according to claim 6, wherein in the length direction, the predetermined cutting segment further comprises:
a buffer portion, located between the support segment and the offset-compensating portion, wherein the buffer portion comprises a transition side edge, the transition side edge extends along a straight line from the second side of the support body to the second side edge, and an extending direction of the first side edge and an extending direction of the transition side edge are parallel to each other.

9. The support strip according to claim 8, wherein in the length direction, a value range of a length of the transition side edge is 20 mm-25 mm.

10. The support strip according to claim 1, wherein the predetermined cutting segment further comprises:
a counterweight portion, arranged at a same side as the covering portion, wherein the counterweight portion is arranged at and protrudes from the first side edge.

11. The support strip according to claim 10, wherein a shape of the counterweight portion is same as a shape of the covering portion.

12. The support strip according to claim 11, wherein the counterweight portion is a quasi-rectangular sheet-like structure, a rounded chamfer is formed at a connecting place between the counterweight portion and the first side edge, and the counterweight portion comprises a rounded corner.

13. The support strip according to claim 12, wherein a value range of a radius R₁ of the rounded chamfer is 2.0 mm-2.5 mm;
a value range of a radius R2 of the corner is 1.0 mm-1.5 mm;

14. The support strip according to claim 12, wherein in the width direction, the counterweight portion comprises a straight side parallel to the width direction, and the straight side is located between the rounded chamfer and the corner.

15. The support strip according to claim 14, wherein a value range of a length L of the straight side is 1.0 mm-1.2 mm.

16. The support strip according to claim 10, wherein in the length direction, a value range of a shortest distance d2 between a predetermined cutting line and the counterweight portion is 4 mm-5 mm.

17. The support strip according to claim 10, wherein in the length direction, a ratio of a length dl of the transition side edge to a shortest distance d2 between a predetermined cutting line and the counterweight portion is 1:6-1:5.

18. The support strip according to claim 1, wherein a shielding strip engaging portion is arranged on the support body of the support segment, and the shielding strip engaging portion is arranged between two adjacent covering portions.

19. The support strip according to claim 18, wherein the shielding strip engaging portion extends in the width direction, and a width of the shielding strip engaging portion is greater than a width of the support body.

20. A net-tensioning method, for performing a net-tensioning process to the support strip according to claim 1, comprising:
stretching in the length direction the two offset-compensating portions opposite to each other in the length direction to obtain the tensioned support strip;
welding the tensioned support strip on a mask frame; and
removing the predetermined cutting segment.
